(19) United States
(12) Patent Application Publication
(10) Pub. No.: US 2020/0225278 A1
(43) Pub. Date: Jul. 16, 2020

(54) WAFER CRACK DETECTION

(71) Applicant: Rudolph Technologies, Inc., Wilmington, MA (US)

(72) Inventor: Hartmut SEEGER, Freiamt (DE)

(21) Appl. No.: 16/744,621

(22) Filed: Jan. 16, 2020

Related U.S. Application Data
(63) Continuation of application No. 62/792,956, filed on Jan. 16, 2019.

(51) Int. Cl. G01R 31/265; G06T 7/00

(52) U.S. Cl. CPC G01R 31/2656; G06T 2207/30148; G06T 7/0006; G06T 7/001

(57) ABSTRACT

A method for identifying cracks in non-planar substrates is herein disclosed. Images of a substrate in a relaxed state are captured and assessed to identify cracks, if any. Assessment may be conducted optically using broad band illumination, laser illumination, or infrared illumination. Mechanisms for carrying out the method are also disclosed.

### CROSS REFERENCE TO RELATED APPLICATION

This Non-Provisional Utility application claims the benefit of the filing date of U.S. Provisional Patent Application No. 62/792,956, filed Jan. 16, 2019, entitled “WAFER CRACK DETECTION” and the entire teachings of which are incorporated herein by reference.

### BACKGROUND

The process of forming integrated circuits used in today's electronic devices often includes a step where a wafer or panel, on or in which integrated circuits are formed or combined, is applied to what is known as a film frame. A film frame is structure used to support a wafer or panel as it is sawn into individual devices. The process of securing a wafer or panel to a film frame can result in cracks forming in the substrate. These cracks can be difficult to identify. What is needed, then, is a method of reliably identifying cracks that may form in a substrate such as a wafer or panel as it is secured to a film frame.

### BRIEF DESCRIPTION OF THE DRAWINGS

FIG. 1 is a representation of a generic semiconductor substrate on a film frame.

FIGS. 2a and 2b schematically represent a semiconductor substrate in a relaxed state and in a stressed, flat state, respectively.

FIG. 3 is a schematic representation of an optical system for detecting cracks and other anomalies on a semiconductor substrate that has a relatively long working distance.

FIG. 4 is a schematic representation of an optical system for detecting cracks and other anomalies on a semiconductor substrate that has a relatively short working distance.

FIGS. 5a, 5b, and 5c are optional aspects of the present disclosure that may be used emphasize the relaxed state in which cracks may be more easily seen.

FIG. 6 is a flowchart showing one embodiment of how aspects of the present disclosure can be carried out.

FIGS. 7a, 7b, and 7c are schematic cross sections of one embodiment of a top plate useful with aspects of the present disclosure.

FIG. 8 is a schematic top view of the top plate shown in FIGS. 7a, 7b, and 7c.

### DETAILED DESCRIPTION

In the following detailed description of the present disclosure, reference is made to the accompanying drawings that form a part hereof, and in which is shown, by way of illustration, specific embodiments in which the present disclosure may be practiced. In the drawings, like numerals describe substantially similar components throughout the several views. These embodiments are described in sufficient detail to enable those skilled in the art to practice the present disclosure. Other embodiments may be utilized and structural, logical, and electrical changes may be made without departing from the scope of the present disclosure. The following detailed description is, therefore, not to be taken in a limiting sense, and the scope of the present disclosure is defined only by the appended claims and equivalents thereof.

FIG. 1 illustrates one type of semiconductor substrate 10 to which the present disclosure may be applied. The term “semiconductor substrate” as used herein generally refers to wafers or panels of various sizes, arrangement, and composition on or into which integrated circuits or portions thereof may be formed. Semiconductor substrates may be made from silicon, sapphire, gallium arsenide, epoxy or composite materials, glasses of various types or some other suitable material. Semiconductor substrates may include an array of singular devices, i.e. multiple individual devices, or an array of packaged devices, each package including more than one discrete integrated circuit. What is more, semiconductor substrates may include interposers and other intermediate structures of the type used in advanced packaging, i.e. in the processes in which packages of multiple integrated circuits are connected to one another.

The substrate 10 of FIG. 1 is a silicon wafer affixed to film 12 supported by a film frame 14. The substrate 10 has an array of integrated circuit devices 16 formed thereon. Unfortunately, the substrate 10 has crack 20 that runs across the entire width of the substrate 10. Note that some cracks 20 may be partial depth or may run for short distances that are less than an entire diameter or chord of a silicon wafer or composite panel. Cracks 20 form for many reasons, but in particular may arise when thinned substrates are applied to the film 12 of a film frame 14. The process of applying a substrate 10 to the film of a film frame involves flattening the substrate 10 against a chuck or platen (not shown) and adhering the film 12 to the reverse side of the flattened substrate 10. For some substrates 10, the act of flattening may cause the substrate 10 to crack. The film 12 is beneficial for cracked substrates 10 as the film 12 retains any portions of the substrate 10 that might otherwise be separated as a result of the crack 20. While only those individual devices on the substrate 10 through which the crack 20 runs are directly affected, it can be problematic to process cracked substrates 10 as portions of the substrate may further crack or even shatter at some subsequent point during processing, thereby contaminating the substrate 10 and the processing, inspection, or handling systems through which the cracked substrate 10 may pass.

Optical inspection is a common method of detecting defects such as cracks 20 that appear on a substrate 10. Bright field and/or dark field illumination are used to capture high resolution images of the substrate 10. These images are assessed to identify anomalies and the anomalies are themselves assessed to determine if they are problematic. Cracks 20 are one type of problematic anomaly. Non-imaging systems using laser scattering may also be used to identify cracks and the like. These types of system are known to those skilled in the art.

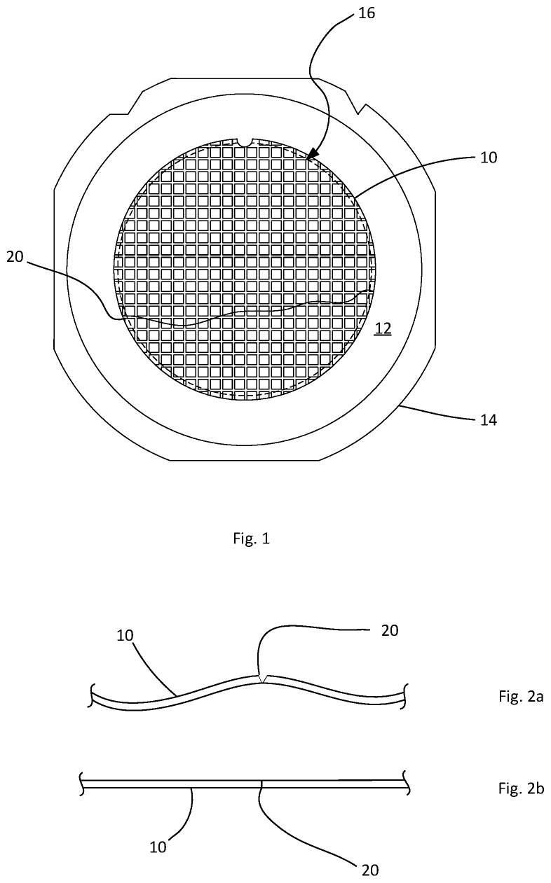

Referring now to FIGS. 2a and 2b there can be seen an example of why it may be difficult to identify cracks in a substrate 10 that is mounted in a film frame 14. In FIG. 2a there can be seen a schematic cross section of substrate 10 having a crack 20 formed through the body of the substrate 10. The wavy shape of the substrate 10 shown in FIG. 2a is indicative of the substrate 10 in a relaxed state. Substrates 10 are nominally or at least near flat at the start of the manufacturing process for integrated circuits. Processing of the substrates 10 can induce internal stresses that are relieved when the substrate 10 is allowed to assume a neutral or relaxed shape as seen in FIG. 2a.

FIG. 2b illustrates the substrate 10 of FIG. 2a in a stressed, flat state. There is a tendency for cracks that were initially formed by flattening substrates 10 to close up in the stressed state and to open up in their relaxed state. Accordingly, it is often the case that a crack 20 will be visible when the substrate 10 is in a relaxed state and difficult to discern when the substrate 10 is in its stressed state.

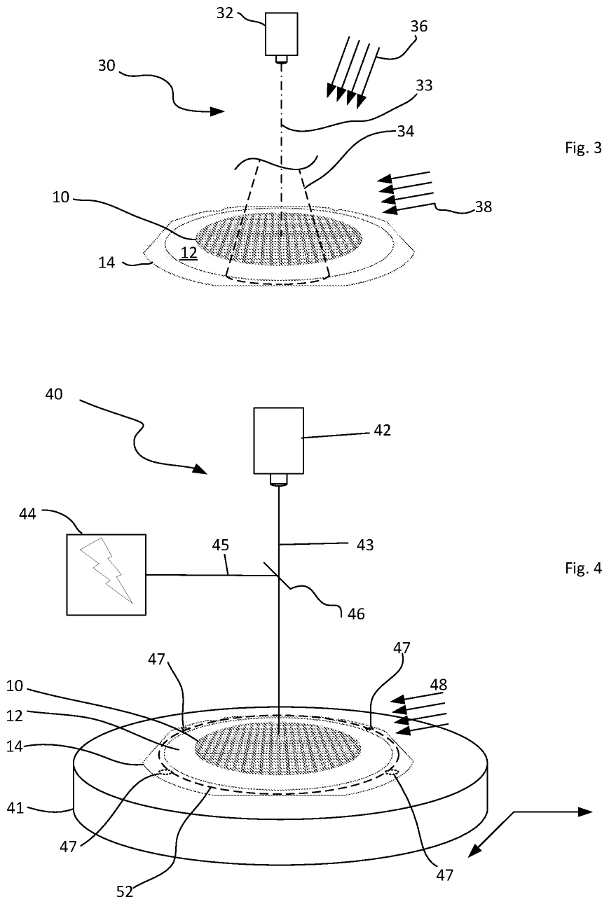

FIGS. 3 and 4 illustrate exemplary imaging systems that may be used for optical inspection of substrates 10 according to embodiments of the present disclosure. FIG. 3 illustrates an imaging system 30 having a relatively long working distance, i.e. distance between a camera 32 and the substrate 10. The relatively long working distance of the camera 32 (and its associated optics) correlates with a relatively large field of view and a lower resolution. The larger field of view may allow the camera 32 to capture an image of the entire substrate 10 at one time or allow relatively fewer images to cover the entire substrate 10. Note that the camera 32 and substrate 10 will have to move relative to one another to permit the capture of images of substantially the entire surface of the substrate 10 where the field of view of the camera 32 is smaller than the area of the substrate 10.

One benefit of a camera 32 having a relatively long working distance is that it may be possible to position a camera 32 within what is known to those skilled in the art as a handler. Substrates are moved from cassettes (not shown) in which they are stored and transported to processing or inspection systems (similarly not shown) by a handler. The handler is an enclosed space that includes one or more robots having one or more end effectors 34 such as that shown in dashed lines in the Figure. The end effector 34 supports a substrate 10 that is secured to a film frame 14. The end effector 34 positions the substrate 10 so that the camera 32 can address the substrate 10. End effectors come in many different styles and arrangements. The end effector 34 illustrated in FIG. 3 is a standard spatulate-type mechanism that supports the substrate 10 on an upper surface that usually has one or more vacuum clamps or suction cups. Edge grip or forficate film frame end effectors are also possible, the requirement being that the end effector 34 must present the upper surface of the substrate 10 to the camera 32 for imaging.

The camera 32 requires illumination to form useable images of the substrate 10. Upper illumination source (arrows 36) is near to, but not quite parallel with the optical axis 33 of the camera 32. This type of illumination is referred to as bright field illumination in that most of the light directed onto the substrate 10 is returned to the camera 32. The field of the view the camera 32 is therefore generally “bright” in that it has a high light intensity. Features on the substrate 10 tend to scatter, absorb, or refract light from the upper source 36, resulting in dark features in the resulting image. Of import is the fact that a tightly closed crack 20 such as that shown in FIG. 2b will reflect most light without much being lost. This results in an image in which the crack may have very low or no differentiation from its surroundings, i.e. the crack is difficult to discern.

Lower illumination source (arrows 38) may be used simultaneous with or in series with the upper illumination source 36. The lower illumination source 38 is incident upon the substrate 10 at a low angle such that most light from the lower source 38 is generally reflected from the substrate 10 and does not enter the camera 32. Features or objects on or in the surface of the substrate 10 will scatter light that subsequently enters the camera 32. As the field of view of the camera 32 is, under the influence of the lower light source 38, generally dark because most light is lost to reflection, only the light scattering features of the substrate 10 such as cracks 20 return light to camera 32. These scattering features appear bright on a dark field. This is referred to as dark field imaging.

Note that as used herein, the term “light” refers to any radiation that is suitable for forming images or for sensing the presences of a crack or similar feature of a substrate 10. This may include white or broadband light, polarized light, coherent light, and light of any useful wavelength or wavelengths. Generally, the wavelength of visible light output by the illumination sources 36 and 38 will be selected to be generally smaller than the features that are of interest. This allows light to be scattered from objects of interest in a relatively predictable manner. In one embodiment, the use of longer wavelength radiation or light may be useful to perform a thermographic inspection of the substrate 10. Rather than taking advantage of the scattering or refraction of light as does standard optical imaging, the camera 32 will be adapted to receive and form images of infrared light emitted by the substrate 10. A source of thermal energy (IR light or a heat source) is directed to the substrate (either or both of sources 36 and 38), warms the substrate 10. This energy is then reemitted as IR radiation and captured by camera 32 to form an image. Because defects or anomalies in the surface of the substrate 10 (including cracks) will emit IR radiation differently than portions of the substrate 10 that are unaffected, anomalies may be readily identified from images of the substrate 10.

FIG. 4 illustrates schematically an imaging system 40 that has a relatively smaller working distance than the imaging system 30. Imaging system 40 is generally of the form of a microscope and will be familiar to those skilled in the art. Note that various optical elements such as lenses, stops, and filters are omitted for simplicity's sake, but are presumed to exist in a standard format.

The imaging system 40 includes a camera 42 having an optical axis 43 that is normal to the substrate 10. The substrate 10 is supported on a top plate or chuck 41 that moves the substrate 10 relative to the camera 42 so that images of the entire substrate 10 may be captured. An illumination source 44 is directed along its own optical axis 45 that is coupled onto the optical axis 43 of the camera 42 by splitter 46. In this way, light from the source 44 is directed down onto the substrate 10 and is then returned through the splitter 46 to the camera 42 to form an image. A lower illumination source 48 is provided as described above to enable dark field illumination of the substrate 10. Light from source 44 is of the bright field type of illumination.

The imaging system 40, as mentioned above, has a generally shorter working distance and smaller field of view. The imaging system 40 also captures images at a much higher resolution. Various resolutions may be selected by changing optical elements such as objectives, which as mentioned above have been omitted form the drawings for simplicity's sake.

The working distance of an imaging system is generally considered to be the distance between the lowermost optical element (often an objective) and the object being imaged, in this case the substrate 10. Because the substrate 10 is imaged in a relaxed state such as that seen in FIG. 2a, the working distance of an imaging system must be sufficient to clear the non-flat topography described by the substrate 10. As one might expect, it is desirable to have the substrate 10 positioned within the depth of field of the imaging system 30 or 40 when an image is formed. This is also referred to as being in focus. Since it likely that portions of the substrate 10 will not share the same focus position, as the surface is topographically varied, the user of imaging systems 10 will have to take images at different focus positions to ensure a desired image quality. This is often done by using a distance sensor in conjunction with the imaging systems 30, 40 to accurately position the field of view of the camera onto the surface of the substrate 10. Alternatively, images of the entire substrate 10 may be captured at a set of discrete focus positions. In this way super-resolution techniques can be used to identify the “in-focus” regions of each image, which can then be concatenated to form an in-focus composite image. Position information for each of the in-focus portions of the images of the substrate 10 can be retained to provide topographic information concerning the substrate 10.

The substrate 10 may be secured to the chuck 41 by means of vacuum clamping. Electrostatic or mechanical means may also be used, but vacuum appears to be more common. As will be appreciated, an end effector (not shown) is used to place the substrate 10 on its film frame on the chuck 41. To allow the substrate 10 to remain in its relaxed state, the film frame 14 is gripped by individual suction cups 47 or by an annular vacuum zone 52 formed into the top of the chuck 41. The substrate 10 itself is not secured to the chuck 41 by vacuum where the relaxed state is desired.

In some instances, cracks 20 form in the substrate 10 in a way such that the crack is closed up in the substrate's 10 relaxed position. And, as described above in conjunction with FIG. 2b, the flat, stressed state is likely to close up any cracks 20 present. It may be possible however, to stress the substrate 10 in ways that do not entirely flatten it. Rather, forces may be applied to the substrate 10 to stress it and cause it to take a shape other than the one it would have in its relaxed state as represented by FIG. 2a, but not necessarily flat or planar as shown in FIG. 2b.

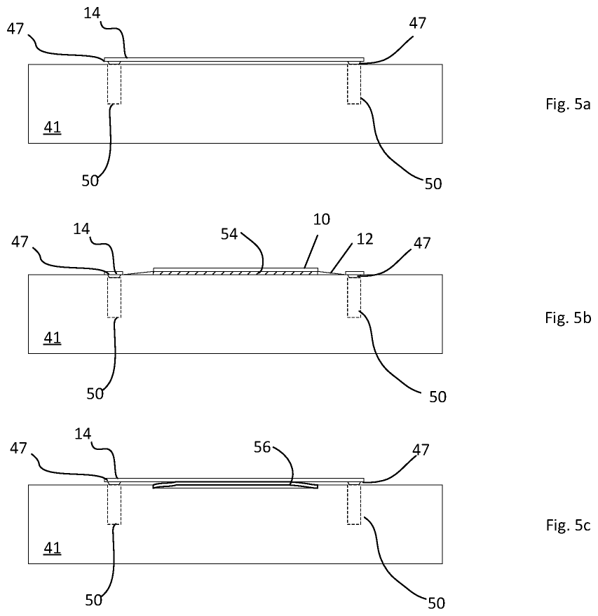

FIGS. 5a, 5b, and 5c show the stressed, non-planar arrangement suggested in the foregoing paragraph. In FIG. 5a, the film frame 14 to which the substrate 10 is attached is supported on suction cups 47 slightly above the surface of the chuck 41. This arrangement is easily facilitated where the suction cups 47 are part of a lift pin 50 that can be readily extended above a top surface of the chuck 41 or retracted into or close to the chuck 41. The arrangement in FIG. 5a may provide a more fully relaxed substrate 10 if the film frame 14 is raised slightly above the surface of the chuck 41 where the substrate would be otherwise stressed by being in contact with the chuck when the film frame 14 is resting upon the chuck. Note that FIG. 5a is essentially a side elevation of the chuck 41 with film frame 14 and lift pin 50 mounted suction cups 47.

FIG. 5b shows an embodiment where the film frame 14 is brought into contact with the surface of the chuck 41, but wherein the film 12 to which the substrate 10 is adhered is supported slightly above the surface of the chuck 41 on a pedestal or puck 54, that may be fixed or moveable, as desired. The difference in height between the substrate 10 and the film frame 14 causes the film 12 to be stretched slightly, thereby opening, to some degree, any cracks that may have formed in the substrate 10. In this way the cracks 20 may be more easily discerned in bright field, dark field, or even thermographic images captured using either of the imaging systems 30 or 40. Care should be taken to not stretch the film 12 too much as it may cause cracks to extend.

FIG. 5c shows another embodiment in which the film frame 14 may be supported above the surface of the chuck 41, though it should be understood that the lift pins 50 could be retracted to bring the film frame 14 into contact with the chuck 41. An elastomeric membrane 56 that has a coefficient of friction higher than the surface of the chuck 41 outside of the membrane is provided. The membrane 56 does not allow for vacuum clamping of the substrate 10 to the chuck 41, but does provide friction that helps keep the substrate 10 in a desired position during imaging. What is more, in some embodiments, the membrane 56 may be slightly inflated to stress the substrate 10 a small amount to help identify cracks 20 in the substrate 10.

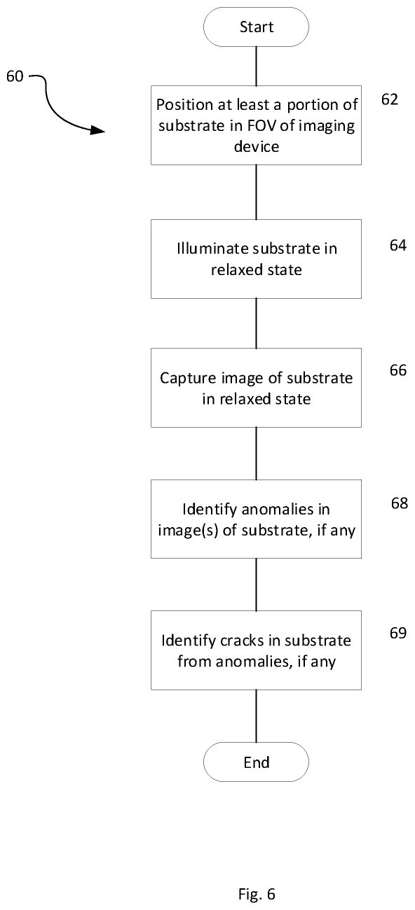

Turning now to FIG. 6, there is illustrated one exemplary method 60 for carrying out the present invention. The method 60 starts at step 62 with positioning at least a portion of the substrate 10 in the field of view of an imaging system such as systems 30 or 40. The substrate 10 is in its relaxed state. The substrate 10 is next illuminated as desired at step 64. A camera 32, 42 or similar sensor is employed at step 66 to capture images of the substrate. Note that relative motion between the camera or sensor and the substrate 10 may be needed to capture images of all or substantially all of the substrate 10. What is more, multiple images of the substrate 10 may be captured at different focal positions of the camera to ensure that proper focus is obtained and/or to obtain topographic information about the substrate in its relaxed position.

Anomalies are identified in the substrate 10 at step 68. Anomalies may be identified in a number of ways. In one embodiment, images of the substrate 10 are compared with a model or reference that represents a nominal or acceptable condition of the substrate 10. This model or reference can be determined statistically from images of the substrate, by using a direct comparison between an image of the substrate and an image of the same or a different substrate that is or should be substantially the same as the image that is under test, or by creating a reference from CAD designs used to generate the structures found on the substrate 10. Another alternative would be to create one or more masks that block light from structures that are not of interest, i.e. block scattered light from acceptable patterns on the substrate 10. In all of these cases, the model or reference is used to identify portions of the captured image that varies from the model or reference by more than some predetermined amount. The predetermined amount correlates to a standard of quality that is established by a user or manufacturer. Where the model or reference allows for only narrow differences, it can be said that the relative quality criteria are high. Where the model or reference allows for wider divergence, it can be said that the relative quality criteria are low.

In yet another embodiment, images of the substrate 10 captured in a relaxed state may be compared to images of the same substrate 10 in a stressed, planar state. Differences related solely to the stress of the substrate may then be identified.

Using dark field illumination, a simple threshholding operation may be used to identify features, such as cracks 20, which strongly scatter light. The lower sources 38, 48 may be used on their own and dialed down in their power to reduce the amount of light that might be scattered from acceptable pattern or nuisance surface roughness, so that strongly scattering features are emphasized in resulting images. In the resulting images, only those regions having an intensity above a specified magnitude will be considered anomalous.

In some cases, bright field illumination may be used to identify cracks that conduct or channel light away from the surface of the substrate 10, thereby revealing the crack as a dark line in the surface of the substrate 10. In other embodiments, a source of IR light (or heat energy) may be used in either of the upper or lower illumination source positions to warm the surface of the substrate 10. A camera 32 or 42 adapted to capture images in IR wavelengths can then be used to identify discrepant portions of the substrate 10. This is a direct result of how structures radiate IR differently where there is a discontinuity in or on the surface of the substrate 10. In other works, a crack 20 will radiate IR light differently than the remainder of the substrate 20.

Not all anomalies are cracks 20 or other defective items. At step 69, anomalous features of a substrate 10 are assessed to determine if they are a crack 20 or other defective aspect. Spatial pattern recognition (SPR) techniques may be used to identify features that extend over larger portions of a substrate 10. This is particularly helpful as cracks 20 tend to extend over large portions of a substrate 10 when they appear.

Once anomalies such as cracks 20 are identified, processing of the substrate may be stopped or modified to ensure a better outcome for the process that produces the substrates 10.

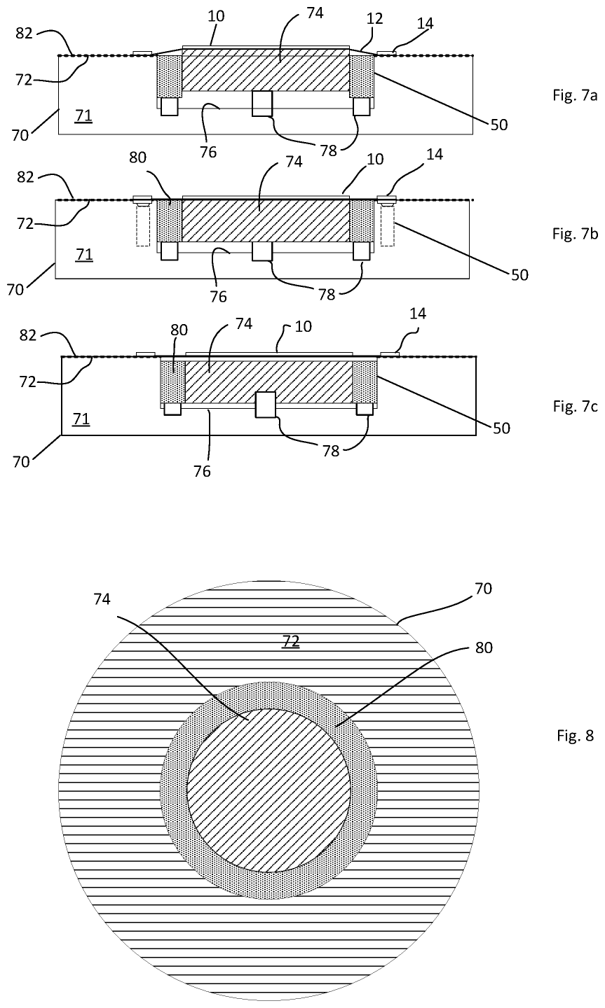

FIGS. 7a, 7b, and 7c illustrate an embodiment of a top plate 70 useful for carrying out an inspection of a substrate 10 on a film frame 14. Top plate 70 is similar in some ways to top plate 41 described herein above. The top plate 70 has a body 71 that is generally secured to a moveable stage (not shown). The top plate 70 is used to move a substrate 10 relative to a camera or other sensor for inspection of the substrate 10. The top plate 70 has an upper surface 72 that is adapted to support at least a portion of a film frame 14. Inlet into the upper surface 72 of the top plate is a moveable puck 74. The puck 74 sits in a cavity 76 formed into the top plate 70 and is moveable within the cavity 76 by means of an actuator 78. The actuator 78 is of any useful configuration, including voice coil, piezoelectric, pneumatic cylinder, linear actuators with a ramp configuration, or the like.

In FIGS. 7a-7c, and FIG. 8, there is shown an optional annular ring 80 that works in much the same way as does the puck 74. The ring 80 is supported by one or more and preferably three, actuators 78 that raise and lower the ring 80. Ring 80 may be omitted where so desired. In the alternative, additional rings (not shown) may be included to accommodate film frames 14 of varying size.

In use, the puck 74 may be placed in three different positions. FIG. 7b illustrates a neutral position of the puck 74 (as well as the optional ring 80). In this position, the puck 74 forms part of the surface 72 of the top plate 70. FIG. 7c illustrates the puck 74 in an inferior position in which the upper surface of the puck 74 is below the surface 72 of the top plate 70. FIG. 7a illustrates the puck 74 in a superior position in which the upper surface of the puck 74 is above the surface 72 of the top plate 70.

Loading a substrate 10 secured to the film 12 of a film frame 14 may be conducted in a number of ways. First, it should be noted that in cases it is customary to lift and move the combined substrate/film frame only by gripping the film frame 14 itself. This is usually done using an end effector (not shown) that grips the film frame 14 using suction cups. This grasp may be from the top or the bottom of the film frame 14. While generally disfavored, the substrate/film frame combination may be supported by resting the combination on a standard spatulate end effector 34 such as the schematic representation shown in FIG. 3. FIG. 7b illustrates the optional inclusion of lift pins 50 in the top plate 70. Lift pins 50 are often used to facilitate the loading and unloading of substrates 10 from a top plate 41 or 70. In a loading position (extended above the surface 72 of the top plate 70), an end effector may set the substrate 10 down on the lift pins.

Other types of end effectors may also be used so long as there is no conflict between the end effector and the lift pins 50. Once the substrate/film frame has been set down upon the lift pins 50, the suction cups 47 of the lift pins are activated to secure the substrate thereto. The lift pins 50 may be moved to a retracted position in which the suction cups 47 are flush with the top surface 72 of the top plate 70. As described in conjunction with FIGS. 5a-5c, the suction cups 47 may also be maintained a bit above the upper surface 72 of the top plate 70. Generally, two or more lift pins 50 with suction cups 47 and preferably three or more are to be utilized to securely grasp the substrate/film frame.

In one embodiment, the loading of the substrate 10 conducted by first raising the puck 74 to its superior position. Note that the actual height of the puck 74 in the superior position of this embodiment must be sufficient to clear the end effector where a bottom grip end effector is used to move the substrate/film frame. The end effector places the bottom surface of the film 12 below the substrate 10 in contact with the upper surface of the puck 74. Where the puck 74 is provided with vacuum clamping mechanisms, vacuum is drawn between the puck and the film to secure the substrate/film frame in place. The end effector is then retracted and the puck is moved to its operative position, be it inferior, neutral, or superior.

The substrate 10 may be placed in its relaxed state by moving the puck 74 and any rings 80 below the surface 72 of the top plate 70. The substrate 10 may be placed in its stressed state by moving the puck 74 to its neutral position. As mentioned above, the puck 74 may be provided with vacuum clamping channels that can secure the substrate 10 to the top plate and coincidentally flatten the substrate 10. Where indicated, additional or different stresses may be placed on the substrate 10 by moving the puck 74 to its superior position. It is noted that in some instances, a substrate 10 may have an inherent relaxed state in which the stress in the substrate 10 and the action of the film 12 on the substrate 10 act to close up any cracks 20 that may exist in the substrate. Where this is the case, it is possible to apply stress to the substrate 10 by inducing stress in the film 12 to which the substrate 10 is adhered. Note that in this instance, vacuum channels in the upper surface 72 of the top plate 70 are activated to secure the film frame 14 to the top plate 70 so that moving the puck 74 to its superior position will induce the aforementioned stress in the film 12 and the substrate 10. Vacuum channels are represented schematically in FIGS. 7a-7c by dashed lines 82. Generally, it will be the case that the upper surface 72 of a top plate 70 will have vacuum channels or the like (note that suction cups in the surface or on lift pins may also perform this function).

In another embodiment the puck 74 and/or rings 80 (if provided) may include, in lieu of vacuum clamping structures, a light source (not shown). The light source is preferably an LED panel enclosed behind a sturdy transparent (to light from the LED) cover that will resist abrasion from the substrate/film frame combination. Vacuum clamping structures or means in the remainder of the surface 72 of the top plate 70 will server to retain the substrate 10 in position for inspection as described hereinabove.

While various examples are provided above, the present disclosure is not limited to the specifics of the examples.

Although specific embodiments of the present disclosure have been illustrated and described herein, it will be appreciated by those of ordinary skill in the art that any arrangement that is calculated to achieve the same purpose may be substituted for the specific embodiments shown. Many adaptations of the present disclosure will be apparent to those of ordinary skill in the art. Accordingly, this application is intended to cover any adaptations or variations of the invention. It is manifestly intended that the present disclosure be limited only by the following claims and equivalents thereof.

What is claimed is:

1. A method of detecting cracks in a semiconductor substrate comprising:
directing light onto a semiconductor substrate, the semiconductor substrate being in a relaxed state;
collecting at least a portion of the light returned from the semiconductor substrate;
forming an image of at least a portion of the semiconductor substrate from the light returned from the semiconductor substrate;
comparing the formed image of at least a portion of the semiconductor substrate with a reference to identify anomalies in the substrate; and
identifying a crack, if any, from among the identified anomalies.

2. The method of detecting cracks in a semiconductor substrate of claim 1 further comprising forming an image of substantially an entirety of a major surface of the semiconductor substrate at one time.

3. The method of detecting cracks in a semiconductor substrate of claim 1 further comprising forming an image of between 25% and 50% of the substrate at one time.

4. The method of detecting cracks in a semiconductor substrate of claim 1 wherein the light directed on to the semiconductor substrate is broadband light and the image formed from light returned from the semiconductor substrate is monochromatic.

5. The method of detecting cracks in a semiconductor substrate of claim 1 wherein the light directed on to the semiconductor substrate is broadband light and the image formed from light returned from the semiconductor substrate includes a representation of the semiconductor substrate in at least two distinct wavelengths.

6. The method of detecting cracks in a semiconductor substrate of claim 1 wherein the light directed on to the semiconductor substrate is infrared light and the image formed from the light returned from the semiconductor substrate represents substantially only infrared light returned from the semiconductor substrate.

7. The method of detecting cracks in a semiconductor substrate of claim 1 wherein the reference against which the formed image is compared is selected from the group consisting of:
a statistical model of at least a portion of the substrate, the statistical model establishing an acceptable level of quality for the at least a portion of the substrate; and
a computer aided design model of at least a portion of the substrate, the computer aided design model establishing an acceptable level of quality for the at least a portion of the substrate.

8. The method of detecting cracks in a semiconductor substrate of claim 1 wherein the reference against which the formed image is compared is selected from the group consisting of:
another formed image that is nominally the same as the formed image under assessment; and
another formed image of the same portion of the semiconductor substrate, the one formed image being captured in a stressed state and the other being captured in a relaxed state.
